(19) United States
(12) Patent Application Publication
(10) Pub. No.: US 2026/0191081 A1
(43) Pub. Date: Jul. 2, 2026

(54) BUMP STRUCTURES FOR FLIP CHIP ON LEADFRAME PACKAGE

(71) Applicant: Texas Instruments Incorporated, Dallas, TX (US)

(72) Inventors: Guangxu Li, Allen, TX (US); Sylvester Ankamah-Kusi, McKinney, TX (US); Jie Chen, Plano, TX (US); Rajen Manicon Murugan, Dallas, TX (US)

(21) Appl. No.: 19/005,725

(22) Filed: Dec. 30, 2024

(51) Int. Cl. H01L 23/00; H01L 21/56; H01L 23/495

(52) U.S. Cl. CPC H10W 74/016; H10W 70/424; H10W 72/01223; H10W 72/01235; H10W 72/0198; H10W 72/221; H10W 72/222; H10W 72/223; H10W 72/232; H10W 72/234; H10W 72/235; H10W 72/248; H10W 72/252; H10W 72/255; H10W 72/923; H10W 72/952; H10W 90/726

(57) ABSTRACT

A semiconductor package comprises a semiconductor die. The semiconductor die comprises a metal pad. The semiconductor package also comprises a leadframe. The semiconductor package further comprises a bump structure between the semiconductor die and the leadframe. The bump structure comprises a first solder portion. The first solder portion is in contact with the metal pad. The bump structure also comprises a second solder portion. The second solder portion is in contact with the leadframe. The bump structure further comprises a metal post between the first solder portion and the second solder portion. The bump structure could reduce stress in BEOL layer of the semiconductor die to improve reliability of the semiconductor package.

### FIELD

The present disclosure relates generally to flip chip on leadframe packages, and more particularly to bump structures to improve reliability for flip chip on leadframe packages.

### BACKGROUND

Semiconductor packaging technologies have evolved in order to adapt to smaller chip sizes made possible by technological advances, as well as increased power dissipation and growing demands for power density. Flip chip on leadframe packaging technologies have become increasingly popular given their electrical benefits and efficient use of printed circuit board area. Flip chip on leadframe packages can replace wire bonded, face-up packages and can reduce problems associated with bond wires. Eliminating bond wires could achieve multiple benefits, such as reduced interconnection inductance and resistance, better utilization of package-to-die area, and improved interconnect density.

When semiconductor devices are mounted on package substrates using flip chip process, a semiconductor die employs conductive post connects that extend from bond pads on an active surface of the semiconductor die to metal traces on the package substrate. In a flip chip package, the semiconductor die is mounted with the active surface facing the package substrate. When the semiconductor die is flip chip mounted to the package substrate, solder bumps deposited between the conductive post connects and the metal traces are heated and allowed to reflow to form solder joints that provide a mechanical connection and electrically couple the semiconductor die to the package substrate. The solder joints mount the conductive post connects to the metal traces on the package substrate to form a flip chip on leadframe package.

### SUMMARY

This summary is provided to introduce a selection of disclosed concepts in a simplified form that are further described below in the detailed description including the drawings provided. This summary is not intended to limit the scope of the claimed subject matter.

Disclosed aspects include a semiconductor package. The semiconductor package comprises a semiconductor die comprising a metal pad. The semiconductor package also comprises a leadframe. The semiconductor package further comprises a bump structure. The bump structure comprises a first solder portion, a second solder portion, and a metal post between the first solder portion and the second solder portion. The metal pad is in contact with the first solder portion and the leadframe is in contact with the second solder portion.

Disclosed aspects include a method of forming a semiconductor package. The method comprises forming a polyimide (PI) layer on a semiconductor wafer and patterning the PI layer. The semiconductor wafer comprises a plurality of metal pads. The method also comprises forming a plurality of first solder portions on the plurality of metal pads. The method also comprises depositing and patterning a photoresist layer on the PI layer. The method also comprises forming a plurality of metal posts on the plurality of first solder portions. The method also comprises removing the photoresist layer. The method also comprises dicing the semiconductor wafer into a plurality of semiconductor dies. The method also comprises forming a second solder portion on each metal post of each semiconductor die. The method also comprises attaching a semiconductor die of the plurality of semiconductor dies to a leadframe. The method further comprises covering the semiconductor die and the leadframe using a mold compound.

### BRIEF DESCRIPTION OF THE DRAWINGS

Reference will now be made to the accompanying drawings, which are not necessarily drawn to scale, wherein:

FIG. 1A is a 3D view of an example semiconductor package having bump structures for stress reduction in accordance with certain aspects of present disclosure;

FIG. 1B is a top perspective view of the example semiconductor package of FIG. 1A;

FIG. 1C is a bottom perspective view of the example semiconductor package of FIG. 1A;

FIG. 1D is a cross-section view of the example semiconductor package of FIG. 1A;

FIG. 2A illustrates simulation results for stress in back-end-of-line layer of a semiconductor package with a first bump structure between a semiconductor die and a leadframe;

FIG. 2B illustrates simulation results for stress in back-end-of-line layer of a semiconductor package with a second bump structure between a semiconductor die and a leadframe;

FIG. 3 illustrates a fabrication process for an example semiconductor package having bump structures for stress reduction in accordance with certain aspects of present disclosure;

FIGS. 4A-4J illustrate cross-section views of the example semiconductor package in each process step of FIG. 3.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

The terms “coupled to” or “couples with” (and the like) as used herein without further qualification are intended to describe either an indirect or direct electrical connection. Thus, if a first device couples to a second device, that connection can be through a direct electrical connection where there are only parasitics in the pathway, or through an indirect electrical connection via intervening items including other devices and connections. For indirect coupling, the intervening item generally does not modify the information of a signal but may adjust its current level, voltage level, and/or power level.

In a flip chip on leadframe package, a semiconductor die is coupled with a leadframe through a series of copper posts that attach directly to metal pads on the semiconductor die. The metal pads generally comprise aluminum (Al) or copper (Cu) and are formed on a back-end-of-line (BEOL) layer of the semiconductor die. The BEOL layer includes metal layers, interlayer dielectric layers, and passivation layers. During component level reliability test for the flip chip on leadframe package, high stress might be generated in the BEOL layer proximate to the copper posts, because copper is a hard material and difficult to deform. Such high stress might cause passivation layer cracking and metal pad plastic deformation, resulting in metal extrusion and electrical shorting failures. Conductive materials, such as solder materials, which are soft and easy to deform, might be considered to replace the copper posts to reduce stress and prevent passivation layer cracking and metal pad plastic deformation. However, large amount of solder materials might introduce bridging issues and might degrade electromigration (EM) performance of the flip chip on leadframe package.

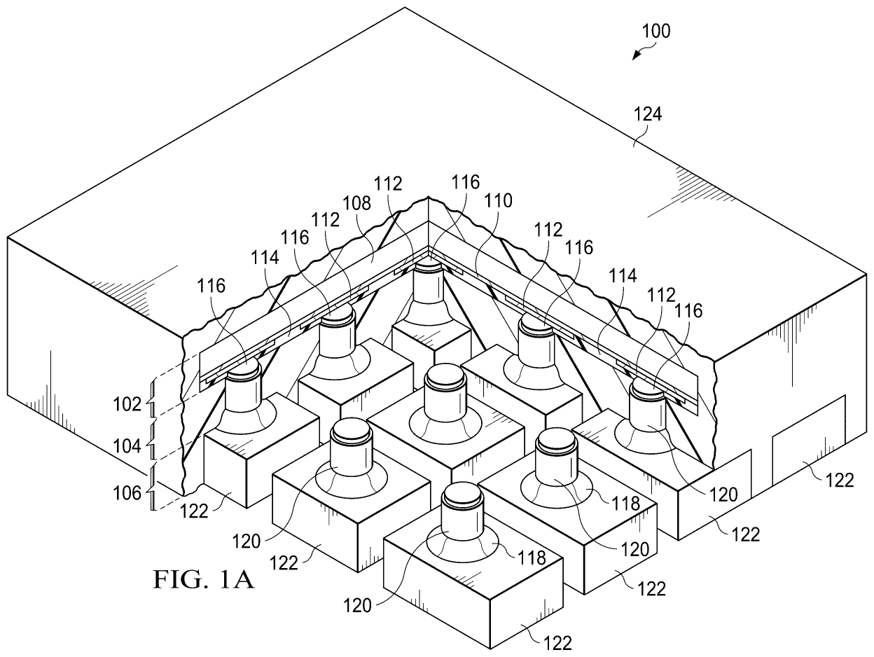

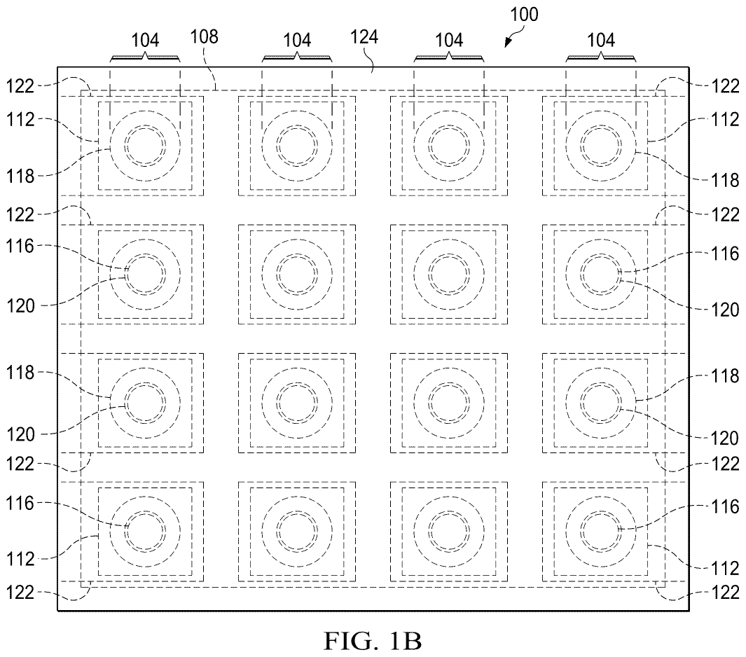

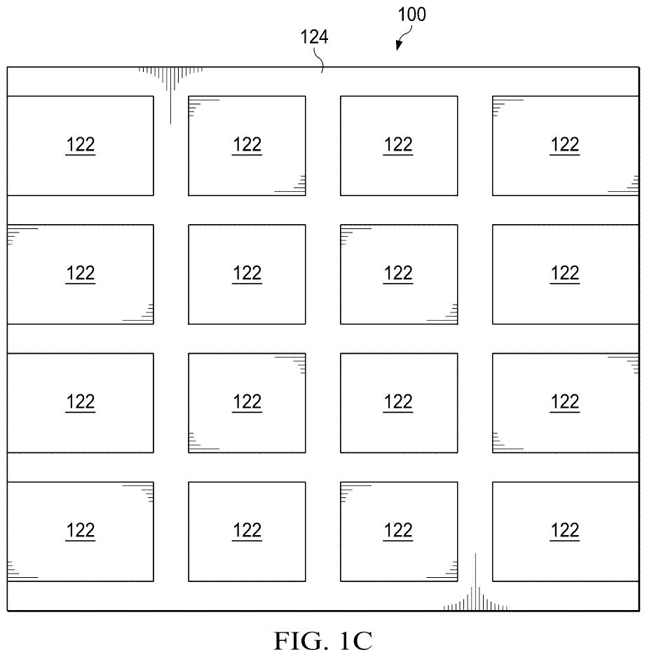

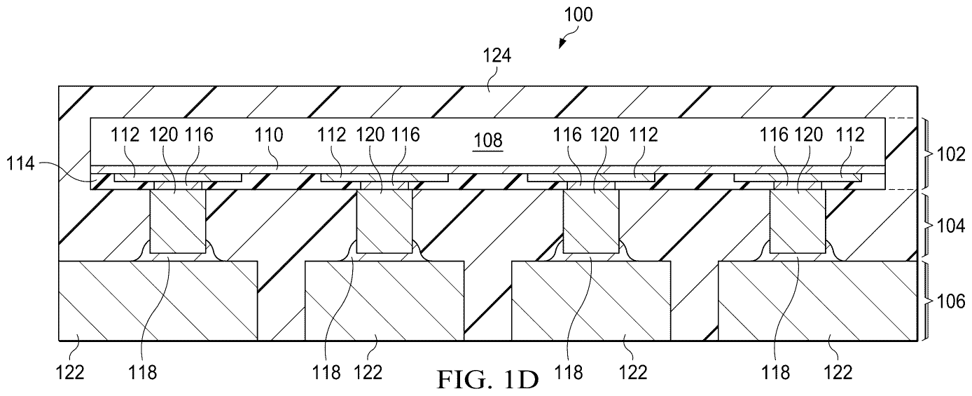

Disclosed aspects include a semiconductor package, such as a flip chip on leadframe package, comprising a semiconductor die, a leadframe, and a plurality of bump structures coupling the semiconductor die to the leadframe. A bump structure refers to connecting structures between metal pads of semiconductor die and leads of leadframe. The plurality of bump structures could reduce stress in BEOL layer of the semiconductor die to improve reliability of the semiconductor package. FIG. 1A is a 3D view of a semiconductor package 100 having bump structures for stress reduction in accordance with certain aspects of present disclosure. FIG. 1B is a top perspective view of the semiconductor package 100 of FIG. 1A. FIG. 1C is a bottom perspective view of the semiconductor package 100 of FIG. 1A. And FIG. 1D is a cross-section view of the semiconductor package 100 of FIG. 1A. The semiconductor package 100 comprises a semiconductor die 102, a plurality of bump structures 104, and a leadframe 106. The semiconductor die 102 comprises a bulk portion 108. The bulk portion 108 may comprise silicon (Si) or other semiconductor materials. The semiconductor die 102 also comprises a BEOL layer 110. The BEOL layer 110 may comprise multiple metal layers, interlayer dielectric layers, and passivation layers. The semiconductor die 102 also comprises a plurality of metal pads 112 on the BEOL layer 110. The plurality of metal pads 112 may comprise Al or Cu. The semiconductor die 102 further comprises a polyimide (PI) layer 114 on the BEOL layer 110 and the plurality of metal pads 112.

In FIG. 1B, the plurality of bump structures 104 comprises 16 bump structures as an example. The plurality of bump structures 104 may comprise any number of bump structures. Each bump structure of the plurality of bump structures 104 comprises a first solder portion 116. The first solder portion 116 is in contact with a metal pad of the plurality of metal pads 112 and the PI layer 114. The first solder portion 116 may comprise SnAgCu (SAC) solder. Sidewalls of the first solder portion 116 may be fully covered by the PI layer 114 or may extend outside of the PI layer 114. Each bump structure of the plurality of bump structures 104 also comprises a second solder portion 118. The second solder portion 118 is in contact with a lead of the leadframe 106. The second solder portion 118 may comprise SAC solder. The first solder portion 116 and the second solder portion 118 may comprise same solder material. When the first solder portion 116 and the second solder portion 118 comprise same solder material, the sidewalls of the first solder portion 116 may be fully covered by the PI layer 114. Thus, during reflow for the second solder portion 118, the PI layer 114 would confine the melted first solder portion 116 and prevent any reliability issues. On the other hand, the first solder portion 116 and the second solder portion 118 may comprise different solder materials. When the first solder portion 116 and the second solder portion 118 comprise different solder materials, the sidewalls of the first solder portion 116 may extend outside of the PI layer 114. The first solder portion 116 may have a higher melting temperature compared to the second solder portion 118. Thus, during reflow of the second solder portion 118, the first solder portion 116 may not melt and would not cause reliability issues even if the sidewalls of the first solder portion 116 extend outside of the PI layer 114. Each bump structure of the plurality of bump structures 104 further comprises a metal post 120 between the first solder portion 116 and the second solder portion 118. The metal post 120 may comprise Cu. The metal post 120 may have a circular cross-section as shown in FIG. 1B as an example. The metal post 120 may have any other shapes of cross-section, such as an oval cross-section. A thickness of each bump structure of the plurality of bump structures 104 may be approximately between 30 μm to 70 μm. A thickness of the first solder portion 116 may be less than one third of the thickness of each bump structure of the plurality of bump structures 104. The first solder portion 116 could reduce stress in the BEOL layer 110 because the first solder portion 116 comprises a solder material which is easy to deform. Thus, the first solder portion 116 can prevent passivation layer cracking in the BEOL layer 110 and metal pad plastic deformation of the plurality of metal pads 112, resulting in improved reliability of the semiconductor package 100. The thickness of the first solder portion 116 may be less than one third of the thickness of each bump structure of the plurality of bump structures 104 in order to leave sufficient Cu volume for the metal post 120 to maintain EM performance of the semiconductor package 100.

The leadframe 106 comprises a plurality of leads 122. The plurality of leads 122 are in contact with the second solder potion 118 of each bump structure of the plurality of bump structures 104. The plurality of leads 122 may comprise Cu. The semiconductor package 100 further comprises a mold compound 124 covering the semiconductor die 102, the plurality of bump structures 104, and the leadframe 106.

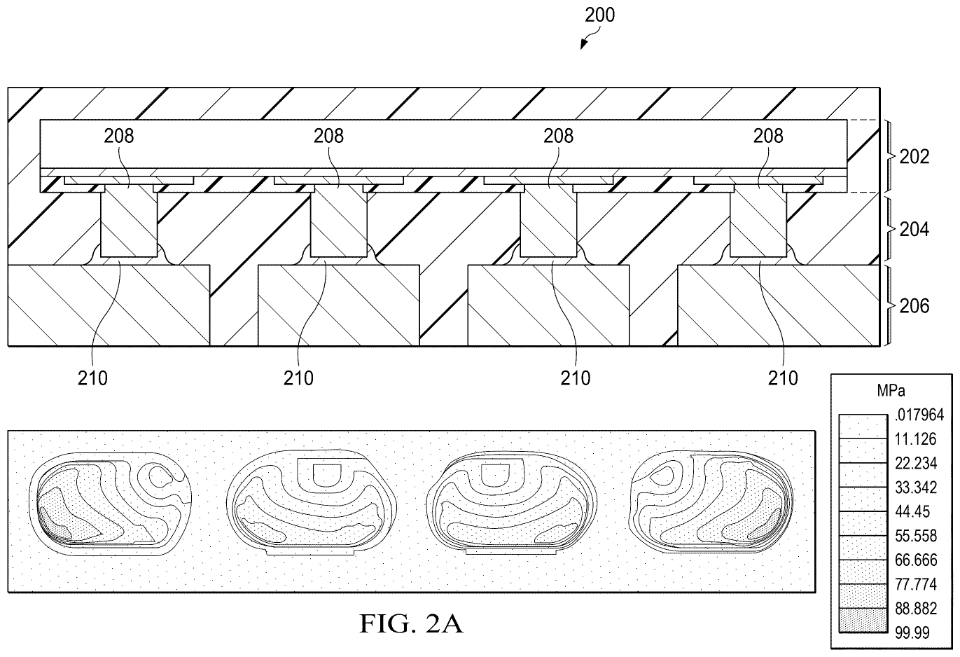

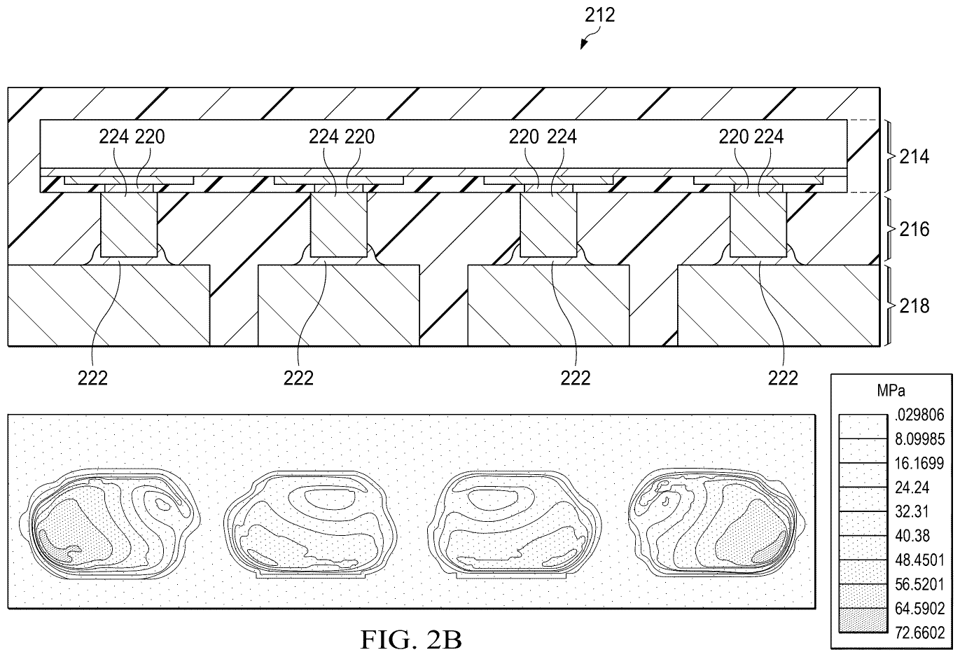

FIG. 2A and FIG. 2B illustrate simulation results for stress in BEOL layers of different semiconductor packages with different bump structures between a semiconductor die and a leadframe. In FIG. 2A, a semiconductor package 200 comprises a semiconductor die 202, a plurality of bump structures 204, and a leadframe 206. The semiconductor die 202 is similar to the semiconductor die 102. The leadframe 206 is similar to the leadframe 106. The plurality of bump structures 204 is different from the plurality of bump structures 104. Each bump structure of the plurality of bump structures 204 comprises a metal post 208. The metal post 208 may comprise Cu. The metal post 208 may have an oval cross-section. The metal post 208 is in direct contact with a metal pad of the semiconductor die 202. There is no solder portion between the metal post 208 and the metal pad of the semiconductor die 202. Each bump structure of the plurality of bump structures 204 further comprises a solder portion 210. The solder portion 210 is in contact with the metal post 208 and a lead of the leadframe 206. The solder portion 210 may comprise SAC solder. Simulation results show maximum stress occurs in the BEOL layer proximate to the leftmost and rightmost bump structures of the plurality of bump structures 204 with a value around 99.99 MPa.

In FIG. 2B, a semiconductor package 212 comprises a semiconductor die 214, a plurality of bump structures 216, and a leadframe 218. The semiconductor die 214 is similar to the semiconductor die 102. The leadframe 218 is similar to the leadframe 106. The plurality of bump structures 216 is similar to the plurality of bump structures 104. Each bump structure of the plurality of bump structures 216 comprises a first solder portion 220. The first solder portion 220 is in contact with a metal pad of the semiconductor die 214. Sidewalls of the first solder portion 220 may be fully covered by a PI layer of the semiconductor die 214. Each bump structure of the plurality of bump structures 216 also comprises a second solder portion 222. The second solder portion 222 is in contact with a lead of the leadframe 218. The first solder portion 220 and the second solder portion 222 may comprise SAC solder. Each bump structure of the plurality of bump structures 216 further comprises a metal post 224 between the first solder portion 220 and the second solder portion 222. The metal post 224 may comprise Cu. The metal post 224 may have an oval cross-section. Simulation results show maximum stress occurs in the BEOL layer proximate to the leftmost and rightmost bump structures of the plurality of bump structures 216 with a value around 72.66 MPa. The simulation results demonstrate that with addition of the first solder portion 220 in each bump structure, the maximum stress in the BEOL layer decreases. Thus, the addition of the first solder portion 220 in each bump structure can prevent passivation layer cracking in the BEOL layer and metal pad plastic deformation of the semiconductor die 214, resulting in improved reliability of the semiconductor package 212.

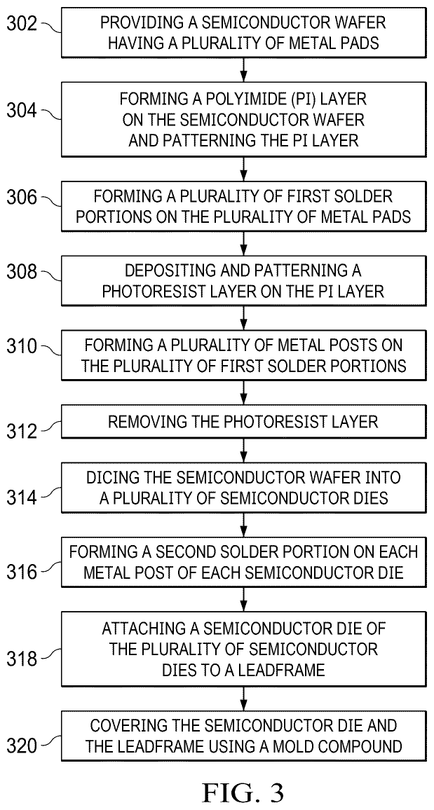

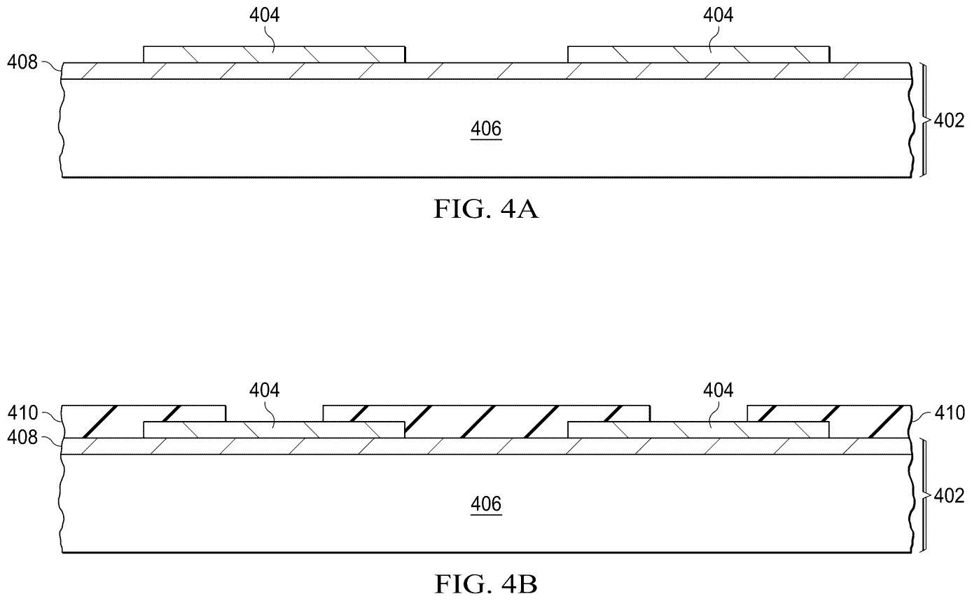

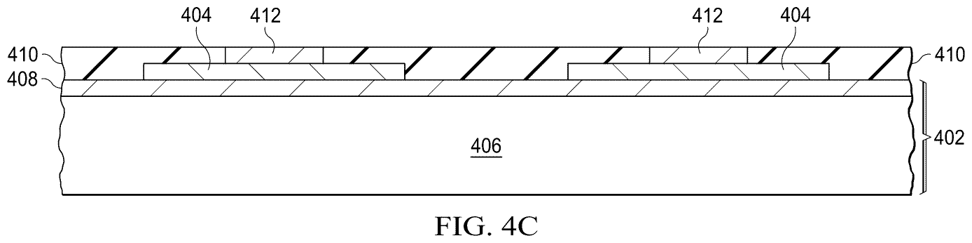

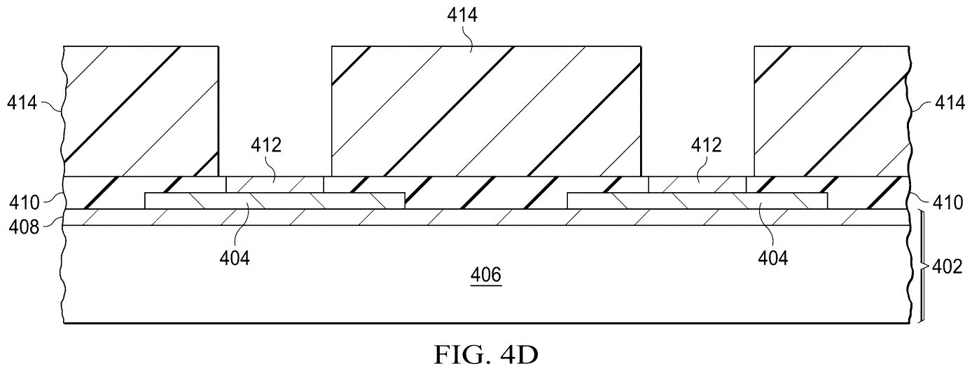

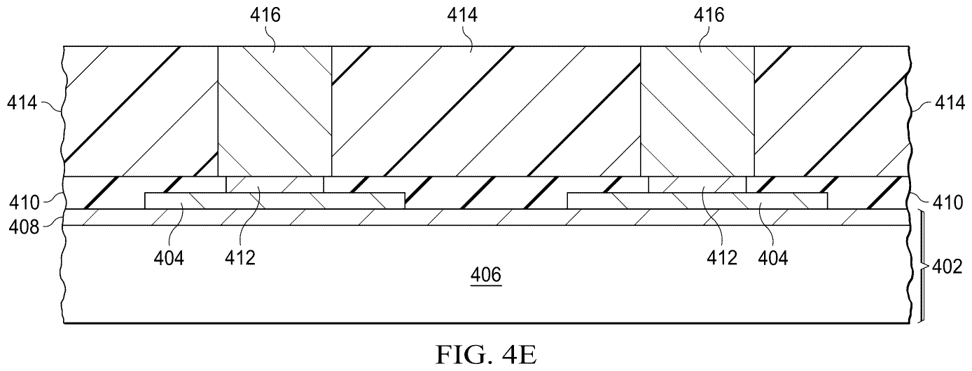

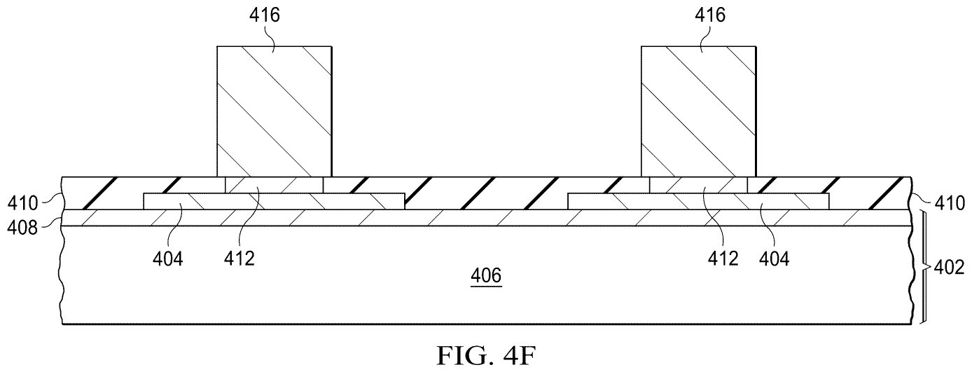

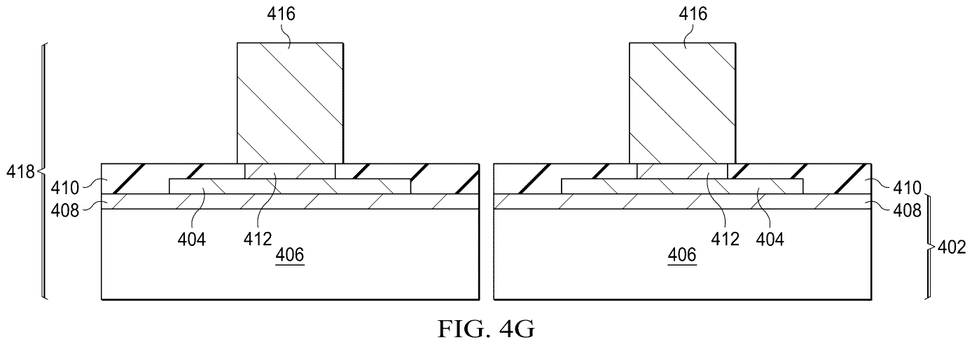

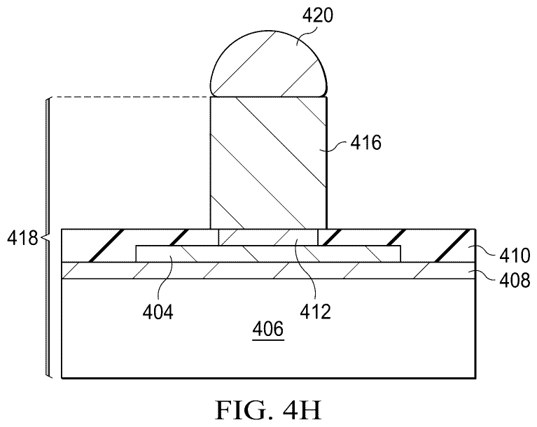

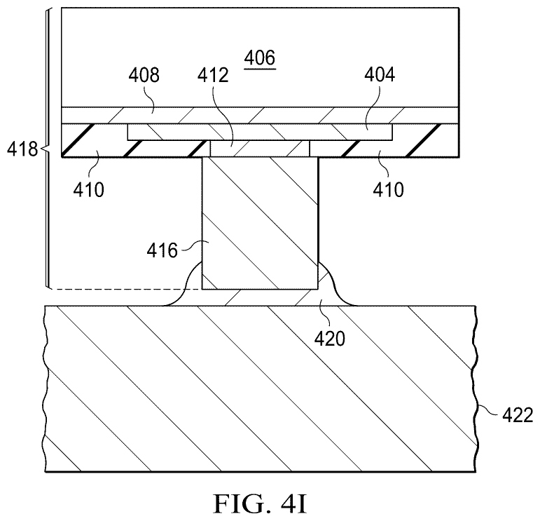

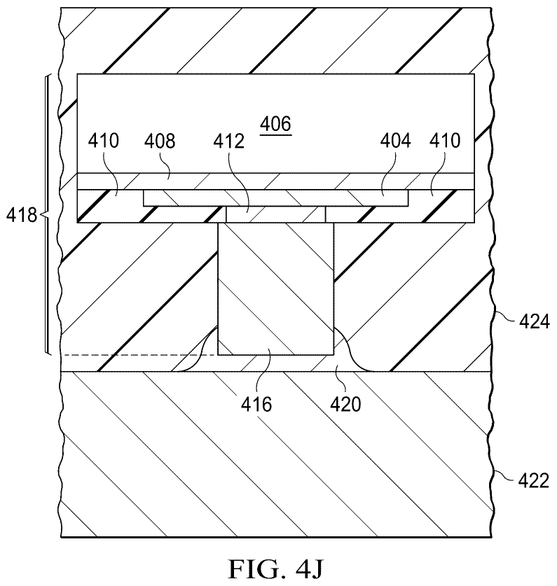

FIG. 3 illustrates a fabrication process for a semiconductor package having bump structures for stress reduction in accordance with certain aspects of present disclosure. FIG. 4A to FIG. 4J illustrate cross-section views of the semiconductor package in each process step of FIG. 3. Accordingly, FIG. 3 and FIG. 4A to FIG. 4J are described in parallel.

Step 302 comprises providing a semiconductor wafer having a plurality of metal pads. As shown in FIG. 4A, a semiconductor wafer 402 has a plurality of metal pads 404 on it. The semiconductor wafer 402 comprises a bulk layer 406 and a BEOL layer 408 on the bulk layer 406. The bulk layer 406 may comprise Si or other semiconductor materials. The BEOL layer 408 may comprise multiple metal layers, interlayer dielectric layers, and passivation layers. The plurality of metal pads 404 may comprise Al or Cu.

Step 304 comprises forming a PI layer on the semiconductor wafer and patterning the PI layer. As shown in FIG. 4B, a PI layer 410 is formed on the semiconductor wafer 402 and patterned to expose the plurality of metal pads 404.

Step 306 comprises forming a plurality of first solder portions on the plurality of metal pads. The plurality of first solder portions may be formed by an electroplating process. As shown in FIG. 4C, a plurality of first solder portions 412 is in contact with the plurality of metal pads 404 and with the PI layer 410. The plurality of first solder portions 412 may comprise SAC solder. Sidewalls of the plurality of first solder portions 412 may be fully covered by the PI layer 410.

Step 308 comprises depositing and patterning a photoresist layer on the PI layer. As shown in FIG. 4D, a photoresist layer 414 is on the PI layer 410 and patterned to expose the plurality of first solder portions 412.

Step 310 comprises forming a plurality of metal posts on the plurality of first solder portions. The plurality of metal posts may be formed by an electroplating process. As shown in FIG. 4E, a plurality of metal posts 416 is on the plurality of first solder portions 412. The plurality of metal posts 416 may comprise Cu.

Step 312 comprises removing the photoresist layer. As shown in FIG. 4F, the photoresist layer 414 is removed.

Step 314 comprises dicing the semiconductor wafer into individual semiconductor dies. As shown in FIG. 4G, the semiconductor wafer 402 is diced into individual semiconductor dies 418. Each semiconductor die 418 comprises one metal post 416 as an example. Each semiconductor die 418 may comprise any number of metal posts 416.

Step 316 comprises for each semiconductor die, forming a second solder portion on each metal post. The second solder portion may be formed by a ball drop or printing process. As shown in FIG. 4H, a second solder portion 420 is on a metal post 416. The second solder portion 420 may comprise SAC solder.

Step 318 comprises attaching an individual semiconductor die to a leadframe. As shown in FIG. 4I, a semiconductor die 418 is attached to a leadframe 422 by the second solder portion 420.

Step 320 comprises covering the individual semiconductor die and the leadframe using a mold compound. As shown in FIG. 4J, the semiconductor die 418 and the leadframe 422 are covered by a mold compound 424 to form a semiconductor package. In such semiconductor package, the plurality of first solder portions can prevent passivation layer cracking in the BEOL layer and metal pad plastic deformation of the semiconductor die, resulting in improved reliability of the semiconductor package.

In example embodiments, the terms “approximately,” “about,” and “around” mean that a value or range of values is either a stated value or range of values or within plus or minus 10% from that stated value or range of values.

Those skilled in the art to which this disclosure relates will appreciate that many variations of disclosed aspects are possible within the scope of the claimed invention, and further additions, deletions, substitutions, and modifications may be made to the above-described aspects without departing from the scope of this disclosure.

What is claimed is:

1. A semiconductor package, comprising:
a semiconductor die comprising a metal pad;
a leadframe; and
a bump structure between the semiconductor die and the leadframe, wherein the bump structure comprises a first solder portion, a second solder portion, and a metal post between the first solder portion and the second solder portion, and wherein the metal pad is in contact with the first solder portion and the leadframe is in contact with the second solder portion.

2. The semiconductor package of claim 1, wherein the metal pad comprises aluminum.

3. The semiconductor package of claim 1, wherein the metal pad comprises copper.

4. The semiconductor package of claim 1, wherein the metal post comprises copper.

5. The semiconductor package of claim 1, wherein the first solder portion and the second solder portion comprise same solder material.

6. The semiconductor package of claim 5, wherein the same solder material comprises SnAgCu (SAC) solder.

7. The semiconductor package of claim 1, wherein the first solder portion and the second solder portion comprise different solder materials.

8. The semiconductor package of claim 7, wherein the different solder materials have different melting temperatures.

9. The semiconductor package of claim 1, wherein a thickness of the first solder portion is less than one third of a thickness of the bump structure.

10. The semiconductor package of claim 1, wherein the semiconductor die comprises a polyimide (PI) layer and wherein sidewalls of the first solder portion are fully covered by the PI layer.

11. A method of forming a semiconductor package, comprising:
forming a polyimide (PI) layer on a semiconductor wafer, the semiconductor wafer comprising a plurality of metal pads, and patterning the PI layer;
forming a plurality of first solder portions on the plurality of metal pads;
depositing and patterning a photoresist layer on the PI layer;
forming a plurality of metal posts on the plurality of first solder portions;
removing the photoresist layer;
dicing the semiconductor wafer into a plurality of semiconductor dies;
forming a second solder portion on each metal post of each semiconductor die;
attaching a semiconductor die of the plurality of semiconductor dies to a leadframe; and
covering the semiconductor die and the leadframe using a mold compound.

12. The method of claim 11, wherein forming the second solder portion comprises a solder ball drop process or a solder printing process.

13. The method of claim 11, wherein forming the plurality of first solder portions comprises an electroplating process.

14. The method of claim 11, wherein forming the plurality of metal posts comprises an electroplating process.

15. The method of claim 11, wherein the plurality of metal posts comprises copper.

16. The method of claim 11, wherein the plurality of first solder portions and the second solder portion comprise same solder material.

17. The method of claim 16, wherein the same solder material comprises SnAgCu (SAC) solder.

18. The method of claim 11, wherein the plurality of first solder portions and the second solder portion comprise different solder materials.

19. The method of claim 18, wherein the different solder materials have different melting temperatures.

20. The method of claim 11, wherein sidewalls of the plurality of first solder portions are fully covered by the PI layer.
